(19) United States
(12) Patent Application Publication
(10) Pub. No.: US 2015/0349385 A1
(43) Pub. Date: Dec. 3, 2015

(54) Method and System for Predicting Useful Life of a Rechargeable Battery

(71) Applicant: Medtronic, Inc., Minneapolis, MN (US)

(72) Inventors: Chao X. Hu, Plymouth, MN (US); Gaurav Jain, Edina, MN (US)

(21) Appl. No.: 14/672,474

(22) Filed: Mar. 30, 2015

Related U.S. Application Data
(60) Provisional application No. 61/973,601, filed on Apr. 1, 2014.

(51) Int. Cl. H01M 10/42; H01M 10/0525; G01R 31/36; H01M 10/06; H01M 10/054; H01M 10/30; H01M 10/052

(52) U.S. Cl. CPC H01M 10/425; H01M 10/30; H01M 10/0525; H01M 10/052; H01M 10/06; H01M 10/054; G01R 31/3651; H01M 2010/4271; H01M 2220/20; H01M 2220/30

(57) ABSTRACT

System and method for predicting the remaining useful life (RUL) of a rechargeable battery, such as a lithium-ion rechargeable battery. In a method, the capacity of the battery is determined based on at least changes of state of charge values estimated at a first and second time and a net charge flow of the battery and applying a particle filter to a capacity degradation formula using the determined capacity to form a capacity degradation model and determining the RUL using the capacity degradation model using a pre-defined end of service threshold. The system and method may be used to predict the RUL of a rechargeable battery in an implantable medical device.

### FIELD OF THE INVENTION

The subject matter of this invention relates to a method for estimating the capacity of a rechargeable battery, and in some embodiments, a Lithium-ion (“Li-ion”) rechargeable battery, and predicting the remaining useful life (RUL) at a charge/discharge cycle throughout the life-time of the battery. The subject matter of the invention also includes medical devices and systems using a rechargeable battery and configured to implement any of the prediction methods described herein to predict the RULs at charge/discharge cycles.

### BACKGROUND

Rechargeable batteries store energy through a reversible chemical reaction. The reusable nature of rechargeable batteries results in a lower total cost of use and more beneficial environmental impact than non-rechargeable batteries. The cell capacity decreases, however, as a battery cell ages. In the case of a Li-ion cell, reduced cell capacity in an aged cell directly limits the electrical performance through energy loss. When Li-ion rechargeable batteries are used as a power source in medical devices that are surgically implanted or connected externally to a patient receiving treatment, the ability to know the condition of that power source is critical. When the medical device is implanted in a patient, the ability for the capacity of the battery to be assessed and the RUL to be predicted throughout the battery life-time to provide information to the patient or the health care provider regarding when the power source must either be replaced or recharged is very useful and could be crucial for minimizing therapy interruptions. Examples of implantable medical devices that may be powered by a rechargeable battery include neurological stimulators, spinal stimulators, and cardiac stimulators such as pacemakers and defibrillators and diagnostic devices such as cardiac monitors. In general, the condition of the battery and its RUL after the battery has been in use for a period of time may be difficult to assess using conventional techniques and an implantable device may be replaced before the battery capacity degrades to an unacceptable level in order to ensure device operation.

Monitoring the battery state of health (SOH) and state of life (SOL) closely by estimating the capacity and predicting the RUL, respectively can result in the effective device maintenance to be administered at an appropriate time, particularly, when the battery is used in an implantable medical device. Currently, a number of methods have been developed to enable optimum use of Li-ion batteries that may be used as power sources for electric vehicles and hybrid electric vehicles. These methods focus on monitoring the SOH by capacity estimation. For example, a joint/dual extended Kalman filter (EKF) (Plett G. L., “Extended Kalman Filtering for Battery Management Systems of LiPB-based HEV Battery Packs Part 3: State and Parameter Estimation,” Journal of Power Sources, v134, n2, p 277-292 (2004) (Plett 1)) and unscented Kalman filter (Plett G. L., “Sigma-point Kalman Filtering for Battery Management Systems of LiPB-based HEV Battery Packs Part 2: Simultaneous State and Parameter Estimation,” Journal of Power Sources, v161, n2, p 1369-1384 (2006) (Plett 2)) with an enhanced self-correcting model have been proposed to simultaneously estimate the state of charge (SOC), capacity and resistance. To improve the performance of joint/dual estimation, adaptive measurement noise models of the Kalman filter have been developed to separate a sequence of SOC and capacity estimation. (Lee S. et al., “State-of-Charge and Capacity Estimation of Lithium-Ion Battery Using a New Open-Circuit Voltage versus State-of-Charge,” Journal of Power Sources, v185, n2, p 1367-1373 (2008)). A physics-based single particle model has also been used to simulate the life cycling data of Li-ion cells and to study the physics of capacity fade. (Zhang Q. et al., “Capacity Fade Analysis of a Lithium Ion Cell,” Journal of Power Sources, v179, n2, p 793-798 (2008); Zhang Q. et al., “Capacity Life Study of Li-Ion Pouch Cells, Part 2: Simulation,” Journal of Power Sources, v179, n2, p 785-792 (2008)) Other techniques for capacity estimation have been developed based on coulomb counting methods. For example, a coulomb counting method with dynamic re-calibration of cell capacity for SOC and capacity estimation is described in Ng K. S. et al., “Enhanced Coulomb Counting Method for Estimating State-of-Charge and State-of-Health of Lithium-Ion Batteries,” Applied Energy, v86, n9, p 1506-1511 (2009) and a coulomb counting method using the approximate entropies of cell terminal voltage and current for capacity estimation is described in Sun Y. H. et al., “Auxiliary Health Diagnosis Method for Lead-Acid Battery,” Applied Energy, v87, n12, p 3691-3698 (2010). A multi-scale computational scheme described in Hu C. et al., “A Multiscale Framework with Extended Kalman Filter for Lithium-Ion Battery SOC and Capacity Estimation,” Applied Energy, v92, p 694-704 (2012) has been developed that decouples the SOC and capacity estimation with respect to both the measurement- and time-scales and employs a state projection schedule for accurate and stable capacity estimation. A system and method for estimating the time before recharging a rechargeable battery in an implantable medical device is described in U.S. Pat. No. 8,314,594 entitled: “Capacity Fade Adjusted Charge Level or Recharge Interval of a Rechargeable Power Source of an Implantable Medical Device, System and Method,” the teachings of which are herein incorporated by reference.

Compared to the battery capacity estimation, a much smaller number of methods have been developed for the battery RUL prediction. An example of such development is a Bayesian framework with the combined use of the relevance vector machine regression and the particle filter (PF). (Saha B. et al., “Prognostics Methods for Battery Health Monitoring Using a Bayesian Framework,” IEEE Transactions on Instrumentation and Measurement, v58, 291-296 (2009)) In this framework, the battery capacity, as an SOH-related parameter essential for the RUL prediction, is inferred from the battery impedance that is measured using electrochemical impedance spectroscopy (EIS). However, EIS measurements require specialized equipment and measurement conditions, which is not suitable for implantable medical device applications. A second example is the application of an improved PF variant-unscented particle filter (UPF) to predicting the battery RUL. (Miao Q. et al., “Remaining Useful Life Prediction of Lithium-Ion Battery with Unscented Particle Filter Technique,” Microelectronics Reliability, v53, 805-810 (2013)). In this application, the capacity of a Li-ion battery is determined by fully charging and discharging the battery which is very time-consuming and only suitable for laboratory testing. Both of these methods predict the battery RUL based on the battery capacity estimates that cannot be practically obtained in implantable medical device applications. Neither one properly addresses the integration of a practical capacity estimation method with the RUL prediction to make the latter feasible in implantable medical device applications.

What is needed is a method for predicting the battery RUL in a simple yet practical manner where the battery capacity is efficiently estimated from readily available measurements (i.e., battery voltage and current), and where the capacity estimation is cohesively integrated with and supports the RUL prediction. The method and system disclosed herein may be used to estimate the battery capacity in a computationally efficient manner, without requiring measurements that cannot be practically obtained, and to project the capacity (estimates) to the end of service (EOS) value (or the EOS threshold) for the RUL prediction. The predicted RUL for Li-ion battery used in implantable medical devices may be used to schedule effective device and/or battery maintenance or replacement in advance to avoid or minimize therapy interruptions.

### SUMMARY OF INVENTION

The present invention relates to methods for predicting the RUL of a rechargeable battery. In one embodiment, a method of predicting RUL of a battery can have the steps of determining a capacity of the battery based on at least changes of state of charge (SOC) values estimated at a first and second time and a net charge flow of the battery; and applying a particle filter to a capacity degradation formula using the determined capacity to form a capacity degradation model; and determining the RUL using the capacity degradation model using a pre-defined end of service (EOS) threshold.

In another embodiment, the present invention provides a system with a medical device having a rechargeable battery, the battery having a voltage, a charge level, an initial capacity and a present capacity. The system additionally includes a processor, operatively coupled to the medical device, and configured to: 1) determine a capacity of the battery based on at least changes of SOC values estimated at a first and second time and a net charge flow of the battery; 2) form a capacity degradation model by applying a particle filter to a capacity degradation formula using the determined capacity; and 3) determine the RUL of the battery using the capacity degradation model and a pre-defined EOS threshold.

In other embodiments, the method of predicting the RUL of a battery can include determining the capacity of a battery based on at least the changes of SOC values and the net charge flow; and forming an exponential capacity degradation model by applying a particle filter with the determined capacity to the following exponential capacity degradation formula:

$${c}_{i} = \frac{{C}_{i}}{{C}_{0}} = 1 - α [ 1 - exp ( - λ i ) ] - β i$$

wherein Cᵢ is the capacity at the i^{th} cycle, C₀ is the initial capacity, a is the coefficient of the exponential component of capacity fade, λ is the exponential capacity fade rate, β is the coefficient of the linear component of capacity fade, and cᵢ is the normalized capacity at the i^{th} cycle; and determining the length of the RUL with the adjusted degradation model with a pre-defined EOS threshold.

In another embodiment, the battery can be selected from any one of a nickel-metal hydride battery, nickel-cadmium battery, lithium-ion polymer battery, lithium-sulfur battery, thin film battery, smart battery, carbon foam-based lead acid battery, potassium-ion battery, and sodium-ion battery. In another embodiment, the battery can be a lithium-ion battery.

In one embodiment, the estimation of capacity of a Li-ion battery can be derived from the formula:

$${C}_{k} = \frac{{\int }_{{t}_{k}}^{{t}_{k + L}} i ( t ) d t}{{SOC}_{k + L} - {SOC}_{k}}$$

wherein Cₖ is the capacity estimate, SOC is the state of charge, k is the index of the measurement time step, and i is the current.

In one embodiment, the particle filter can be selected from a group consisting of a standard sequential importance sampling and resampling particle filter, a standard sequential importance sampling particle filter, a standard sequential importance resampling filter, an extended Kalman filter, an unscented Kalman filter, and a Gauss-Hermite particle filter.

In one embodiment, the optimal proposal importance density used in a particle filter can be derived from formula:

q(xᵢ|x_{0:i-1},y_{1:i})=p(xᵢ|xᵢ₋₁,yᵢ)

wherein x is a vector of state estimates and y is a vector of system observations.

In one embodiment, determination of RUL by the Gauss-Hermite particle filter can include determining the capacity of at the i^{th} cycle; determining system transition and measurement function; determining posterior PDF of the normalized capacity by the Gauss-Hermite particle filter; predicting normalized capacity forward by cycle number; determining RUL for each particle; and determining RUL distribution.

In one embodiment, the determination of capacity of at the i^{th} cycle can use the capacity fade model formula

$${c}_{i} = \frac{{C}_{i}}{{C}_{0}} = 1 - α [ 1 - exp ( - λ i ) ] - β i$$

wherein Cᵢ is the capacity at the i^{th} cycle, C₀ is the initial capacity, a is the coefficient of the exponential component of capacity fade, λ is the exponential capacity fade rate, β is the coefficient of the linear component of capacity fade, and cᵢ is the normalized capacity at the i^{th} cycle.

In one embodiment, the determination of system transition and measurement function can use formulas:

cᵢ=1−αᵢ₋₁[1−exp(−λᵢ₋₁i)]−βᵢ₋₁i+uᵢ,αᵢ=αᵢ₋₁+r_{1,i},λᵢ=λᵢ₋₁+r_{2,i},βᵢ=βᵢ₋₁+r_{3,i} Transition:

yᵢ=cᵢ+vᵢ Measurement:

wherein yᵢ is the capacity measurement at the i^{th} cycle, and u, r₁, r₂, r₃ and v are the Gaussian noise variables with zero means.

In another embodiment, determination of posterior PDF of the normalized capacity of the Gauss-Hermite particle filter can use formula:

$$p ( {c}_{i} \vert {y}_{1 \text{:} i} ) \approx \frac{1}{{N}_{P}} {\sum }_{i = 1}^{{N}_{P}} δ ( {c}_{i} - {c}_{i}^{j} )$$

wherein cᵢ^{j} is the j^{th} particle after the resampling step at the i^{th} cycle.

In one embodiment, prediction of normalized capacity forwarded by a cycle number can use formula:

$$p ( {c}_{i + l} \vert {y}_{1 \text{:} i} ) \approx \frac{1}{{N}_{P}} {\sum }_{i = 1}^{{N}_{P}} δ ( {c}_{i + l} - {c}_{i + l}^{j} )$$

wherein cᵢ₊ₗ^{j}=1−αᵢ^{j}[1−exp(−λᵢ^{j}(i+l))]−βᵢ^{j}(i+l); N_{P} is the number of particles, δ is the Dirac delta function, cᵢ^{j} is the j^{th} particle after the resampling step at the i^{th} cycle, αᵢ^{j} is the coefficient of the exponential component of capacity fade, λ is the exponential capacity fade rate, and βᵢ^{j} is the coefficient of the linear component of capacity fade.

In another embodiment, determining the RUL for each particle can use formula:

Lᵢ^{j}=root[αᵢ^{j}[1−exp(−λᵢ^{j}i)]+βᵢ^{j}i=0.25]−i

wherein αᵢ^{j} is the coefficient of the exponential component of capacity fade, λ is the exponential capacity fade rate, and βᵢ^{j} is the coefficient of the linear component of capacity fade and wherein the EOS threshold is defined as 75% of the normalized capacity.

In one embodiment, determining the RUL distribution can use formula:

$$p ( {L}_{i} \vert {y}_{1 \text{:} i} ) \approx \frac{1}{{N}_{P}} {\sum }_{i = 1}^{{N}_{P}} δ ( {L}_{i} - {L}_{i}^{j} )$$

wherein N_{P} is the number of particles, and is the Dirac delta function.

In another embodiment, the EOS threshold can be defined between 20%-90% of the normalized capacity.

In one embodiment, the EOS threshold can be defined between 30%-80% of the normalized capacity.

In another embodiment, the EOS threshold can be defined between 40%-70% of the normalized capacity.

In one embodiment, the EOS threshold can be defined between 50%-60% of the normalized capacity.

In another embodiment, an apparatus for predicting the RUL of a battery can include a circuit capable of determining the capacity of a Li-ion battery based on at least the changes of SOC values and the net charge flow; applying the particle filter technique to adjust with the capacity value an exponential capacity degradation model; and determining the length of the RUL with the adjusted capacity degradation model with a pre-defined EOS threshold.

In one embodiment of the apparatus, the exponential capacity degradation model can be expressed by the formula:

$${c}_{i} = \frac{{C}_{i}}{{C}_{0}} = 1 - α [ 1 - exp ( - λ i ) ] - β i$$

wherein Cᵢ is the capacity at the i^{th} cycle, C₀ is the initial capacity, α is the coefficient of the exponential component of capacity fade, λ is the exponential capacity fade rate, β is the coefficient of the linear component of capacity fade, and cᵢ is the normalized capacity at the i^{th} cycle.

### BRIEF DESCRIPTION OF FIGURES

FIG. 1 is a flow chart of a method for predicting the RUL of a rechargeable battery.

FIG. 2 shows a Li-ion battery equivalent circuit model (or lumped parameter model), which considers the effects of open circuit voltage (OCV), series resistance (Rₛ), diffusion resistance (R_{d}), and diffusion capacitance (C_{d}).

FIG. 3 shows the effects of capacity on projection of SOC.

FIG. 4 shows the cycling performance of cells manufactured and cycled between 2002 and 2012.

FIGS. 5A and 5B show the voltage curve evolution in a weekly cycling test.

FIG. 5A plots the voltage versus normalized discharge capacity curves at cycles 15 (0.3 years on test), 215 (3.5 years), 415 (6.5 years) and 615 (9.3 years) and FIG. 5B plots the voltage versus DOD curves at these four cycles.

FIGS. 6A and 6B show the plot of OCV as a function of DOD with state projection zone (FIG. 6A) and the plot of normalized net charge flow as a function of normalized discharge capacity (FIG. 6B).

FIGS. 7A-7D show the capacity estimation results of cell 1 (FIG. 7A), cell 2 (FIG. 7B), cell 3 (FIG. 7C) and cell 4 (FIG. 7D), respectively. Results are plotted every 50 cycles for ease of visualization.

FIGS. 8A and 8B show the RUL prediction results of cell 1. FIG. 8A plots the capacity tracking and RUL prediction by the GHPF at cycle 200 (results are plotted every 20 cycles for ease of visualization) and FIG. 8B plots the RUL predictions by the GHPF at multiple cycles throughout the life-time.

FIG. 9 shows a block diagram of the method for predicting the RUL of a battery.

FIG. 10 shows an implantable medical device implanted in a patient.

### DETAILED DESCRIPTION

### Definitions

Unless defined otherwise, all technical and scientific terms used herein generally have the same meaning as commonly understood by one of ordinary skill in the relevant art.

The articles “a” and “an” are used herein to refer to one or to more than one (i.e., to at least one) of the grammatical object of the article. For example, “an element” means one element or more than one element.

An “adjusted capacity degradation model” is a model used to predict the remaining useful life of a battery. An adjusted capacity degradation model can be formed by determining the capacity of a battery based on at least the changes of SOC values and a net charge flow of the battery, and applying a particle filter to adjust with the determined capacity a capacity degradation model formed using a capacity degradation formula.

The term “battery” as used herein refers to a device consisting of one or more electrochemical cells that convert stored chemical energy into electrical energy. The definition of battery can include a rechargeable battery.

The term “capacity,” is defined as the available electric charge stored in a fully charged cell. As used in the present invention, the capacity can be an indicator of the health condition of the battery cell.

A “capacity degradation model” is expressed by a capacity degradation formula.

The term “capacity fade” refers to the capacity loss during cycling of a battery. In the exponential capacity degradation model, a is the coefficient of the exponential component of capacity fade, λ is the exponential capacity fade rate, and β is the coefficient of the linear component of capacity fade.

An “exponential capacity degradation model” is a model with an exponential component, represented for example by the equation:

$${c}_{i} = \frac{{C}_{i}}{{C}_{0}} = 1 - α [ 1 - exp ( - λi ) ] - βi$$

wherein Cᵢ is the capacity at the i^{th} cycle, C₀ is the initial capacity, α is the coefficient of the exponential component of capacity fade, λ is the exponential capacity fade rate, β is the coefficient of the linear component of capacity fade, and cᵢ is the normalized capacity at the i^{th} cycle.

An “extended Kalman filter” (EKF) means a nonlinear version of the Kalman filter. The EKF implements a Kalman filter for a system dynamic that results from the linearization of the original non-linear filter dynamics around state estimates.

The “end of service (EOS) threshold” is a pre-defined percentage of the normalized capacity of a battery, and can be used to determine the remaining useful life of a battery.

The “unscented Kalman Filter” (UKF) means an extension of the unscented transformation to a recursive estimation. When the state transition and observation models are highly non-linear, UKF can represent the true mean and covariance of the estimate using a selection of a minimal set of sigma points around the mean.

The “Gauss-Hermite particle filter” (GHPF) can be used in signal and image processing associated with Bayesian dynamical models. The GHPF uses the “Gauss-Hermite Kalman filter” (GHKF) to generate a proposal density. The GHPF as defined herein propagates sufficient statistics for each particle based on the latest system observations, in order to build a representative proposal density.

A “hybrid capacity degradation model” is a capacity degradation model having both an exponential and a linear component.

The term “normalized capacity” refers to the capacity of a battery in terms of discharge time that has been normalized to a common scale.

A “particle filter” is a general term to describe estimation algorithms. Various particle filters include standard sequential importance sampling particle filter, standard sequential importance resampling particle filter, extended Kalman filter, unscented Kalman filter and Gauss-Hermite particle filter, among others. A particle filter, as a sequential Monte Carlo method, implements the recursive Bayesian filter by simulation-based methods.

The term “posterior probability density function” (posterior PDF) refers to the conditional probability of a random event after relevant evidence is taken into account.

“Remaining useful life” (RUL) of a battery can be determined using the adjusted capacity degradation model using a “pre-defined EOS threshold.” Degradation modeling is based on probabilistic modeling of a degradation mechanism, degradation path and comparison of a projected distribution to a pre-defined EOS threshold.

A “processor” can be used for calculating the RUL of a battery, and may be integrated into the device in which the battery is used, or may be an external system. The processor may alternatively be a component of a separate device, and may determine the SOC and net charge flow when the battery is inserted into this separate device and may be an electrical circuit. Information about the RUL of the battery may be transmitted wirelessly or via wires from a separate device to the processor and from the processor to a display or the separate device.

The term “proposal importance density” refers to an estimated density for use in the particle filter. The optimal proposal importance density is q(xᵢ|x_{0:i-1},y_{1:i})=p(xᵢ|xᵢ₋₁,yᵢ) which utilizes the information carried by both the most recent state estimates xᵢ₋₁ and system observations yᵢ.

A “rechargeable battery” means a type of battery in which the electrochemical reactions are electrically reversible such that the battery may be recharged.

The term “remaining useful life” (RUL) means remaining longevity and refers to the available service time left before the capacity fade reaches an unacceptable level where the unacceptable level can be chosen and/or selected according to certain requirements.

The “state of charge” (SOC) is the percentage of remaining charge in a battery relative to the full battery capacity. “State of charge values” refers to the specific percentages.

The term “system transition” refers to a change in the system over time. The normalized capacity changes as a battery is used; the system transition refers to the change in the normalized after a period of time t, including the changes due to the linear and exponential components.

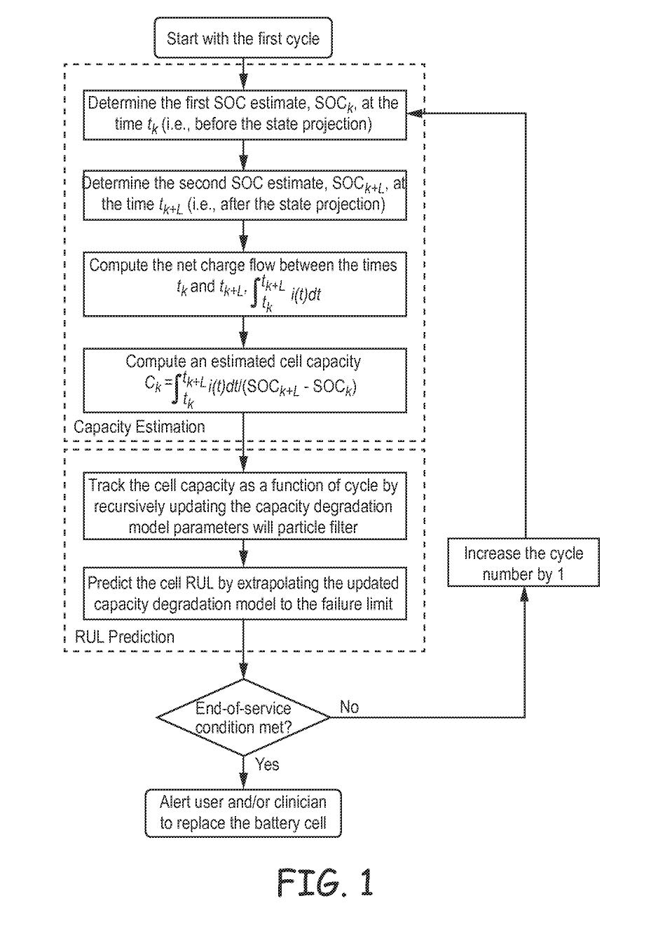

An embodiment of a method of determining the RUL of a battery is shown in FIG. 1. In certain embodiments, the method can be thought of as including two modules. The first module conducts a capacity estimation. The estimations from this module are utilized in the second module, which predicts the RUL. At the first cycle, the SOC estimate is made before the state projection as described below. The SOC is estimated again at some time after the state projection. The net charge flow between these two times is calculated, and from the net charge flow and SOC values the cell capacity is estimated. The cell capacity as a function of the cycle is tracked by the second module by recursively updating the capacity fade model parameters using the particle filter, which in this embodiment is the GHPF, as described below. The updated capacity fade model is extrapolated to the EOS threshold to predict the RUL. If the EOS condition is met, the computation stops and a user and/or clinician is alerted to replace the battery. If not, the computation is repeated by increasing the cycle number by one until the results meet the EOS condition.

### Capacity Estimation

The present invention relates to estimating the capacity of the battery cell in a dynamic environment at every charge/discharge cycle, based on a discrete-time dynamic model that describes the behavior of the cell and knowledge of the measured electrical signals. The present invention can also predict how long the electrical cell can be expected to last before the capacity fade reaches an unacceptable level. It will be understood that an acceptable level as defined herein can be a level set by an operator. Alternatively, the acceptable level can be determined by the minimum required functions that can depend on the battery requirements. The level deemed to be unacceptable can be calculated or determined from provided specifications.

The present invention further provides a method for predicting the RUL of a battery such as a Li-ion battery at each charge/discharge cycle throughout the whole life-time of the cell. The method can be applied to a battery of any dimensions including a Li-ion battery, but would only be applicable to a rechargeable battery where the capacities can be reversed and repeatedly measured every charge/discharge cycle. The systems and any processor or electrical circuit useful to predict the RUL of a battery are configured to apply the methods of the invention and enable anticipation of, and early detection of abnormal capacity fade trend. Abnormal capacity fade trend can result from a soft/hard short or any other manufacturing defect/abuse, or use conditions whether predictable or unpredictable. The present invention further prevents impending failures from occurring by producing an early warning that can be critically important for use with an implantable medical device providing therapy to a patient.

The method of the present invention has in certain embodiments, two modules that can be dedicated to capacity estimation and RUL prediction, respectively. The first module, the capacity estimation module, can utilize two open circuit voltage measurements (V1 and V2) before and after a partial charge (or discharge) period. Based on the relationship between open circuit voltage and SOC, the two open circuit voltage measurements can be converted to two states of charge values (SOC1 and SOC2). In addition, the net charge flow (ΔQ) can be computed by integrating the current (measured by coulomb meter) over the charge (or discharge) period. Based on the net charge flow and the SOC measurements, the capacity (C) can be estimated using the following equation: C=ΔQ/|SOC1−SOC2|.

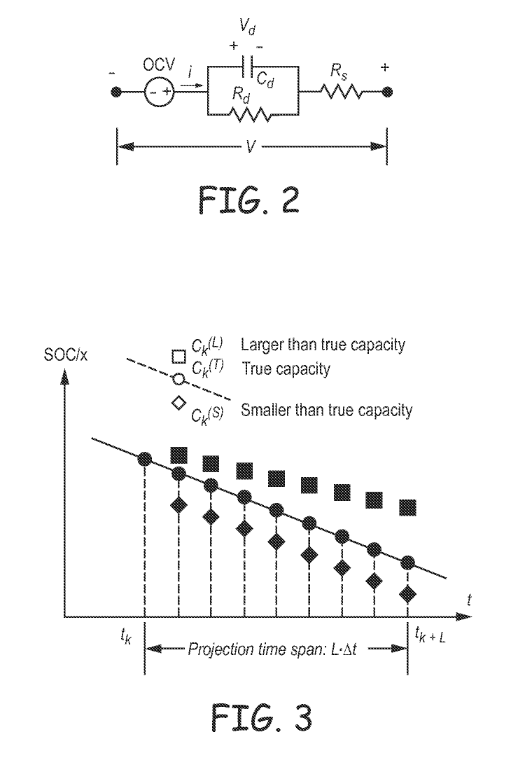

In order to estimate the SOC in a dynamic environment, one embodiment includes a cell dynamic model (FIG. 2) that relates the SOC to the cell terminal voltage. The SOC of a cell can change rapidly, and depending on the use condition, can transverse the entire range of 100%-0% within minutes. In contrast to the rapidly varying behavior of the SOC, the cell capacity tends to vary slowly and typically decreases 1.0% or less in a month with regular use. The model contemplated by the present invention accounts for the effects of OCV, series resistance (Rₛ), diffusion resistance (R_{d}), and diffusion capacitance (C_{d}). The model expresses the cell terminal voltage as the formula (1)

Vₖ=OCV(SOCₖ)−iₖ·Rₛ−V_{d,k} (1)

where OCV is the open circuit voltage, i is the current, Rₛ is series resistance, V_{d} is the diffusion voltage and k is the index of the measurement time step.

Since there is a strong correlation between the SOC and OCV, the SOC can be estimated from the OCV of the cell. The state transition equation of the diffusion voltage can be expressed as formula (2)

$${V}_{d , k + 1} = {V}_{d , k} + ( {i}_{k} - \frac{{V}_{d , k}}{{R}_{d}} ) \cdot \frac{Δ t}{{C}_{d}} \qquad ( 2 )$$

where R_{d} is the diffusion resistance, C_{d} is the diffusion capacitance, and Δt is the length of measurement interval. The time constant of the diffusion system can be expressed as τ=R_{d}C_{d}. It is noted that, after a sufficiently long duration (e.g., 5τ) with a constant current iₖ, the system reaches the final steady state with a final voltage V_{d}=iₖ·R_{d} and the cell terminal voltage becomes Vₖ=OCV(SOCₖ)−iₖ(Rₛ+R_{d}).

Given the discrete-time cell dynamic model described above and the measured electrical signals (i.e., cell current and terminal voltage), the SOC can be estimated by using one of the approaches such as the extended/unscented Kalman filter and the coulomb counting technique. In certain embodiments, the proposed capacity estimation method can utilize the SOC estimates before and after the state projection to estimate the capacity. Based on a capacity estimate Cₖ, the state projection projects the SOC through a time span LΔt, expressed as the formula (3)

$${SOC}_{k + L} = {SOC}_{k} + \frac{{\int }_{{t}_{k}}^{{t}_{k + L}} i ( t ) d t}{{C}_{k}} \qquad ( 3 )$$

The effect of the capacity on the projected SOC is graphically explained in FIG. 3, where the projected SOCs with larger/smaller-than-true capacity estimates exhibit positive/negative deviations from their true values under a constant current discharge. Projected SOCs with larger-than-true capacity estimates exhibit positive deviations from their true values, while SOCs with smaller-than-true capacity estimates exhibit negative deviations from their true values. The observation implies: (1) the capacity can significantly affect the SOC estimation and inaccurate capacity estimation leads to inaccurate SOC estimation; and (2) the SOCs before and after the state projection, if accurately estimated based on the voltage and current measurements, can be used along with the net charge flow to back estimate the capacity, which can be mathematically expressed as the formula (4)

$${C}_{k} = \frac{{\int }_{{t}_{k}}^{{t}_{k + L}} i ( t ) d t}{{SOC}_{k + L} - {SOC}_{k}} \qquad ( 4 )$$

It will be understood that at the start of every state projection (i.e., at the time tₖ), an accurate SOC estimate can be used to project through the projection time span LΔt according to the state projection equation. Upon the completion of every state projection (i.e., at the time t_{k+L}), an accurate SOC estimate can be used to complete the capacity estimation. It is important to note that the accuracy in the SOC estimation is one key factor that affects the accuracy in the capacity estimation. In order to maintain accuracy in the capacity estimation in the presence of an inaccurate SOC estimation, the present invention contemplates ensuring a large cumulated charge to compensate for any inaccuracy in the SOC estimation.

In other embodiments, the SOC values can be determined by using a joint/dual extended/unscented Kalman filter with an enhanced self-correcting model approach (Plett G. L., “Extended Kalman Filtering for Battery Management Systems of LiPB-based HEV Battery Packs Part 3: State and Parameter Estimation,” Journal of Power Sources, v134, n2, p 277-292 (2004) (Plett 1); Plett G. L., “Sigma-point Kalman Filtering for Battery Management Systems of LiPB-based HEV Battery Packs Part 2: Simultaneous State and Parameter Estimation,” Journal of Power Sources, v161, n2, p 1369-1384 (2006) (Plett 2)) or a coulomb counting technique with dynamic re-calibration of cell capacity (Ng K. S. et al., “Enhanced Coulomb Counting Method for Estimating State-of-Charge and State-of-Health of Lithium-Ion Batteries,” Applied Energy, v86, n9, p 1506-1511 (2009)).

### RUL Prediction

The second module, the RUL prediction module, can use a particle filter technique to adaptively adjust an exponential capacity degradation model with newly estimated capacity values obtained from Module 1 and can project the capacity to an EOS value using a latest degradation model, which determines the length of the RUL. In certain embodiments, the particle filter can be a sequential Monte Carlo method for model estimation, which estimates the probability distribution functions of model parameters based on a set of random particles and their associated weights.

In one embodiment, a nonlinear state-space model is defined as the formula (5)

Transition: xᵢ=ƒ(xᵢ₋₁,θᵢ₋₁)+uᵢ,θᵢ=θᵢ₋₁+rᵢ,

Measurement: yᵢ=g(xᵢ,θᵢ)+vᵢ (5)

where xᵢ is the vector of system states at the time tᵢ=i·ΔT, with ΔT being a fixed time step between two adjacent measurement points, and i being the index of the measurement time step, respectively; θᵢ is the vector of system model parameters at the time tᵢ; yᵢ is the vector of system observations (or measurements); uᵢ and rᵢ are the vectors of process noise for states and model parameters, respectively; vᵢ is the vector of measurement noise; and ƒ(•,•) and g(•,•) are the state transition and measurement functions, respectively. With the system defined, both the system states x and model parameters θ can be inferred from the noisy observations y.

In a Bayesian framework, it will be understood that the posterior probability distribution functions (PDFs) of the states given the past observations, p(xt|y1:i), constitutes a statistical solution to the inference problem described in formula (5) and properly captures the uncertainties of the states. The recursive Bayesian filter enables a continuous update of the posterior PDFs with new observations. In certain embodiments, the particle filter, such as a sequential Monte Carlo method, can implement the recursive Bayesian filter by simulation-based methods. In the particle filter, the state posterior PDFs can be built based on a set of particles and their associated weights, both of which are continuously updated as new observations arrive, expressed as in the formula (6)

p(xᵢ|y_{1:i})≈Σᵢ₌₁^{N}^{_{P}}wᵢ^{j}δ(xᵢ−xᵢ^{j}) (6)

where {xᵢ^{j}}ⱼ₌₁^{N}^{_{P}} and {wᵢ^{j}}ⱼ₌₁^{N}^{_{P}} are the particles and weights estimated at the i^{th} measurement time step, respectively; and N_{P} is the number of particles. The standard particle filter algorithm follows a standard procedure of sequential importance sampling and resampling (SISR) to recursively update the particles and their associated weights:
(1) Initialization (i=0)

For j=1, 2, . . . , NP, randomly draw state samples x0j from the prior distribution p(x0).

(2) For i=1, 2, . . .

(a) Importance Sampling
For j=1, 2, . . . , NP, randomly draw samples from the proposal importance density xᵢ^{j}˜q (xᵢ|x_{0:i-1}^{j},y_{1:i}). The standard SISR particle filter employs the so-called transmission prior distribution q(xᵢ|x_{0:i-1}^{j},y_{1:i})=p(xᵢ|xᵢ₋₁^{j}).
For j=1, 2, . . . , NP, evaluate the importance weights of formula (7)

$${w}_{i}^{j} = {w}_{i - 1}^{j} \frac{p ( {y}_{i} \vert {x}_{i}^{j} ) p ( {x}_{i}^{j} \vert {x}_{i - 1}^{j} )}{q ( {x}_{i} \vert {x}_{0 : i - 1}^{j} , {y}_{1 : i} )} \qquad ( 7 )$$

For j=1, 2, . . . , NP, normalize the importance weights of formula (8)

\tilde{w}ᵢ^{j}=wᵢ^{j}[Σⱼ₌₁^{N}^{_{P}}wᵢ^{j}]⁻¹ (8)

(b) Selection (Resampling)
Multiply/suppress samples {xᵢ^{j}}ⱼ₌₁^{N}^{_{P}} with respect to high/low importance weights to obtain NP random samples {xᵢ^{j}}ⱼ₌₁^{N}^{_{P}} with equal weights NP−1.

(c) Posterior PDF Approximation with formula (6).

It is noted that the performance of the particle filter largely depends on the choice of the proposal importance density. The optimal proposal importance density is q(xᵢ|x_{0:i-1},y_{1:i})=p(xᵢ|xᵢ₋₁,yᵢ) which utilizes the information carried by both the most recent state estimates xᵢ₋₁ and system observations yᵢ. The proposal density used in the standard SISR particle filter does not exploit the latest system observations yᵢ. Moreover, when the observations contain outliers (i.e., the observations are not informative) or when the observations have a small noise variance (i.e., the observations are very informative), the standard SISR filter can often result in poor performance. One principle means to better approximate the optimal proposal density is to use local linearization using standard nonlinear filter methodologies to generate the proposal density.

Primarily applied to tracking and vision, the GHPF filter as described herein can be used in many areas of signal and image processing associated with Bayesian dynamical models, in which the latent variables are connected in a Markov chain and the objective is to determine the distributions of the latent variables at a specific time, given all observations up to that time. It is understood that efforts in pursuit of a better proposal density resulted in the development of the Gauss-Hermite particle filter (GHPF) which uses the Gauss-Hermite Kalman filter (GHKF) to generate the proposal density. (Ito K., et al., “Gaussian filters for nonlinear filtering problems,” IEEE Transactions on Automatic Control, v45, p 910-927 (2000); Yuan Z. et al., “The Gauss-Hermite Particle Filter,” Acta Electronica Sinica, v31, n7, p 970-973 (2003)) The GHPF is based on the “Gauss-Hermite quadrature integration” and does not require the evaluation of the Jacobian matrix as understood by those of ordinary skill in the art. The Jacobian matrix is the matrix of all first-order partial derivatives of a vector-valued function. The GHPF does not require the evaluation of the Jacobian matrix or the first-order partial derivatives. In general, GHPF is computationally less expensive to evaluate the first-order partial derivatives as compared to the EKF and so the GHPF filter technique is computationally attractive. The main idea of the GHPF is to propagate sufficient statistics for each particle based on the latest system observations, in order to build a more representative proposal density. The proposal density generated by running the GHKF allows the movement of the particles in the prior distribution to the regions of high likelihood.

In applying the GHPF to predict RUL of a Li-ion battery, the underlying capacity fade model can be expressed as an exponential function using formula (9)

$${c}_{i} = \frac{{C}_{i}}{{C}_{0}} = 1 - α [ 1 - exp ( - λi ) ] - βi \qquad ( 9 )$$

where Cᵢ is the capacity at the i^{th} cycle, C₀ is the initial capacity, α is the coefficient of the exponential component of capacity fade, λ is the exponential capacity fade rate, β is the coefficient of the linear component of capacity fade, and cᵢ is the normalized capacity at the i^{th} cycle. It was reported that the exponential function captures the active material loss and the hybrid of linear and exponential functions provides a good fit to three years' cycling data. (Brown J. et al., “A Practical Longevity Model for Lithium-Ion Batteries: De-coupling the Time and Cycle-Dependence of Capacity Fade,” 208th ECS Meeting, Abstract #239 (2006)) The normalized capacity and the capacity fade rate are treated as the state variables. The system transition and measurement functions can then be written as formula (10)

Transition: cᵢ=1−αᵢ₋₁[1−exp(−λᵢ₋₁i)]−βᵢ₋₁+uᵢ,αᵢ=αᵢ₋₁+r_{1,i},λᵢ=λᵢ₋₁+r_{2,i},βᵢ=βᵢ₋₁+r_{3,i}

Measurement: yᵢ=ΔCᵢ+vᵢ (10)

In formula (10), yᵢ is the capacity measurement at the i^{th} cycle, and u, r₁, r₂, r₃ and v are the Gaussian noise variables with zero means.

At the i^{th} cycle, the posterior PDF of the normalized capacity is approximated by the GHPF as formula (11)

$$p ( {c}_{i} \vert {y}_{1 \text{:} i} ) \approx \frac{1}{{N}_{P}} {\sum }_{i = 1}^{{N}_{P}} δ ( {c}_{i} - {c}_{i}^{j} ) \qquad ( 11 )$$

where cᵢⱼ is the j^{th} particle after the resampling step at the i^{th} cycle. The prediction of the normalized capacity forward by 1 cycles can be expressed as formula (12)

$$p ( {c}_{i + l} \vert {y}_{1 \text{:} i} ) \approx \frac{1}{{N}_{P}} {\sum }_{i = 1}^{{N}_{P}} δ ( {c}_{i + l} - {c}_{i + l}^{j} ) \qquad ( 12 )$$

where cᵢ is shown by formula (13)

cᵢ₊₁^{j}=1−αᵢ^{j}[1−exp(−λᵢ^{j}(i+l))]−βᵢ^{j}(i+l) (13)

In certain embodiments, the RUL (in cycles) can be obtained for each particle as the number of cycles between the current cycle and the EOS cycle by formula (14)

Lᵢ^{j}=root[αᵢ^{j}[1−exp(−λᵢ^{j}i)]+βᵢ^{j}i=0.25]−i (14)

It will be understood that formula (14) can be used if 75% of the normalized capacity is defined as the EOS threshold.

In other embodiments, the failure threshold can be defined as any in the range of 50 to 99.9% with an adjustment to formula (14) to account for the change in the normalized capacity being defined as the EOS threshold. For example, in formula (14), the value of 0.25 can be replaced with 0.20 if 80% of the normalized capacity is defined as the EOS threshold. In general, it will be understood that x=1−EOS threshold (%), as shown in formula (15)

Lᵢ^{j}=root[αᵢ^{j}[1−exp(−λᵢ^{j}i)]+βᵢ^{j}i=x]−i

In certain embodiments, the RUL distribution can be built based on the particles derived from formula (14) or (15), and be expressed as formula (16)

$$p ( {L}_{i} \vert {y}_{1 \text{:} i} ) \approx \frac{1}{{N}_{P}} {\sum }_{i = 1}^{{N}_{P}} δ ( {L}_{i} - {L}_{i}^{j} ) \qquad ( 16 )$$

As shown, the present invention provides for a complete derivation of the RUL distribution as approximated by the GHPF. It will be understood that the RUL prediction can use the GHPF technique to adaptively adjust an underlying capacity fade model with newly estimated capacity values from the state projection and can project the capacity to the EOS value with the latest fade model in order to determine the length of the RUL.

It will be understood by those of ordinary skill that various versions of particle filters proposed such as the standard SIS particle filter, standard SISR particle filter, EKF-PF, UKF-PF, GHPF, and are contemplated by the present method and can be used in the methods and systems thereof. One of ordinary skill in the art will further understand that the standard SISR particle filter is only one of many types of particle filters that can be applied in the present invention.

It will be understood that the standard SISR particle filter employs the so-called transmission prior distribution as the proposal importance density, which does not exploit the latest system observations, while the GHKF utilizes the latest system observations to build a more representative proposal density that allows the movement of the particles in the prior distribution to the regions of high likelihood. Moreover, the purposes of the GHPF and dual EKF methods can be different. The GHPF in the present invention can model the capacity fade trend based on capacity estimates and predict the RUL, while the purpose of the dual EKF can be to estimate the SOC and capacity.

The present invention contemplates the present methods being applied to various types of rechargeable batteries including nickel-metal hydride (“NiMH”) battery, nickel-cadmium (“NiCd”) battery, Lithium-ion (“Li-ion”) battery, Lithium-ion polymer (“LiPo”) battery, Lithium sulfur battery, Thin film battery, Smart battery, Carbon foam-based lead acid battery, Potassium-ion battery, and Sodium-ion battery. The method is not limited to the battery types as described herein, but can instead be applied to any battery or equivalents thereof as practicable and understood as being applicable by those of ordinary skill. The most prevalent rechargeable batteries on the market today are Li-ion, NiMH, Lithium-ion polymer, and NiCd batteries, and it will be understood that the present methods can be particularly well adapted for use such in such batteries. Moreover, the invention can be used with rechargeable batteries in many technologies, including but not limited to, tablets, laptops, medical devices, portable media players, power tools, automobile starters, automobiles, motorized wheelchairs, golf carts, electric bicycles, and electric forklifts, or cars. In particular, Li-ion batteries are frequently used in almost all fields where a rechargeable battery is applicable, including but not limited to the technologies and applications described herein. The present invention can be used to estimate RUL in applications requiring an optimal energy-to-mass ratio and minimal loss of capacity. The present invention can also be applied to miniaturized devices and applications, and other optimally weight-saving applications requiring high energy density such as in portable electronic devices, mobile phones, PDAs (personal digital assistant), and notebook personal computers.

One skilled in the art will recognize that the processor or an electrical circuit used for calculating the RUL can be integrated into the device in which the battery is used, or can be an external system. The methods of constructing such a processor based on the methods described herein are well known and can be fabricated by those of ordinary skill depending on the specific application. It is noted that the present method can be advantageously in conjunction with medical devices that may be implanted in the human body. Where the processor is external to a device in which the battery is used, the detection of the SOCs and net charge flow may be made by the device in which the battery is used and transmitted, either wirelessly or wired, to the processor. Alternatively, the processor may be a component of a separate device, and may determine the SOC and net charge flow when the battery is inserted into this device.

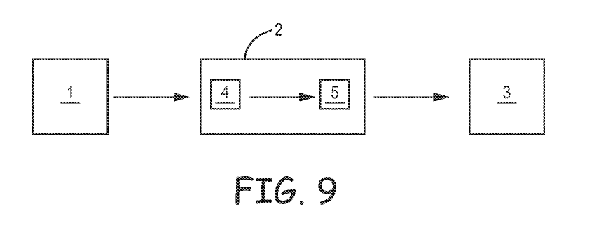

FIG. 9 shows one possible block diagram of the method using a processor. The SOC and net charge flow measurements 1 are entered or transmitted, either wirelessly or wired, from a separate device or electronic componentry of a device into a processor 2. From those measurements, the cell capacity 4 can be determined by the processor 2. The processor 2 then utilizes the particle filter described herein to form the capacity degradation model 5. Using this model, and a pre-set EOS threshold, the processor 2 can estimate the RUL of the battery. The processor 2 then transmits the RUL estimate to the user 3 by displaying the RUL.

In certain embodiments, the processor contemplated by the present invention may include any one or more of a microprocessor, a controller, a digital signal processor (DSP), an application specific integrated circuit (ASIC), a field-programmable gate array (FPGA), or equivalent discrete or integrated logic circuitry adapted for using the method of the present invention. In certain embodiments, the processor can include multiple components, such as any combination of one or more microprocessors, one or more controllers, one or more DSPs, one or more ASICs, or one or more FPGAs, as well as other discrete or integrated logic circuitry. The functions attributed to the processor may be embodied as software, firmware, hardware or any combination thereof. In particular, any processor contemplated by the present invention can have a microprocessor configured to monitor RUL and make the necessary calculations based on capacity estimates stored in memory. The processor may receive input data from the batteries contained in implantable medical devices while operating in a patient and provide alerts or messaging via wireless control to a base module connected wirelessly to the implantable device. Alternatively, the device may provide an audible alert or signal an alert during a routine monitoring session. In still other embodiments, a user and/or clinician can interface and receive the RUL estimates. Alternatively, the RUL estimates can take the form of a battery health indicator providing an easy and convenient means for providing an alert for when the battery needs to be replaced.

In particular, the two modules described herein for capacity estimation and RUL prediction can be configured to contain the described processors or electronic componentry. For example, Module 1, which is the capacity estimation module, can be adapted to receive the two open circuit voltage measurements (V1 and V2) before and after a partial charge (or discharge) period and use such measurements to perform the capacity estimation calculations. Based on the relationship between open circuit voltage and SOC, a processor can use the two open circuit voltage measurements to convert the two states of charge values (SOC1 and SOC2), and compute the net charge flow (ΔQ) by integrating the current (measured by coulomb meter) over the charge (or discharge) period (not shown). In other embodiments, Module 2, which is the RUL prediction module, can contain another processor or electrical circuit or rely on the same processor to perform the calculations for a particle filter technique as described herein to adaptively adjust an exponential capacity degradation model with newly estimated capacity values obtained from Module 1 and project the capacity to an EOS value using the latest degradation model.

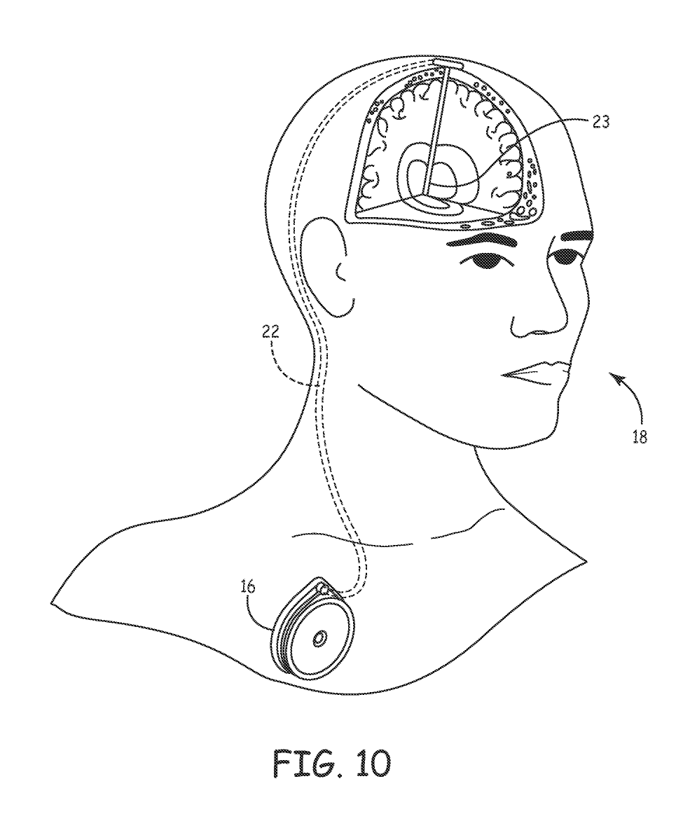

A system with an implantable medical device having a rechargeable battery with which the methods of the invention are useful in predicting the RUL of the battery is depicted generically in FIG. 10, which shows implantable medical device 16, for example, a neurological stimulator, implanted in patient 18. Implantable medical device 16 can be any of a number of medical devices configured with a therapy delivery component such as lead 22 operatively connected to the medical device to deliver therapy to a patient at a desired therapeutic delivery site 23. Examples of such medical devices include implantable therapeutic substance delivery devices, implantable drug pumps, electrical stimulators, cardiac pacemakers, cardioverters or defibrillators or diagnostic devices such as cardiac monitors.

When a rechargeable battery is used as the power source of an implantable medical device (e.g., neurological stimulator, spinal stimulator, pacemaker and defibrillator) or an external medical device (e.g., insulin pump, patient controlled analgesia pump and ventricular assist device), the methods can be used to inform the patient and/or the patient's health care provider, such as his/her clinician on how long the device can be used before the replacement should occur. Because capacity is updated every cycle to account for the aging effects, the method can be expected to produce an accurate estimate of RUL. The present methods and systems allow a clinician to schedule a replacement near the EOS so that the device can be left implanted as long as possible and, at the same time, avoid jeopardizing patient safety. For example, an implantable pacemaker, cardioverter, and/or defibrillator that provides therapy to the heart of a patient via electrodes having a Li-ion battery can be advantageously monitored by the methods and apparatuses of the present invention.

In certain embodiments, a telemetry module having any suitable hardware, firmware, software or any combination thereof known to those of ordinary skill for communicating with another device, can transmit the RUL or any other calculation obtained from battery monitoring. Under the control of the processor, the telemetry module can receive downlink telemetry from and send uplink telemetry to a programmer or base module with the aid of an antenna, which may be internal and/or external. The processor can also provide the data to be uplinked and the control signals for the telemetry circuit within the telemetry module via an address/data bus. In other embodiments, the telemetry module can provide received data to the processor via a multiplexer or any other suitable methods and systems. In other embodiments, a telemetry module can communicate with the processor in the implanted medical device using RF communication techniques supported by telemetry modules known to those of ordinary skill.

In other embodiments, the processor can transmit the RUL and any other obtained measurement or calculated values to a programmer or base module. Alternatively, the programmer or base module may electrically interrogate the processor or implantable medical device as needed. The processor and/or implanted medical device can store the RUL and/or calculated values within memory and retrieve the stored values from memory upon receiving an instruction from a program or base module. The processor may also generate and store data containing the obtained calculations based on the measurements collected from the voltage terminals and transmit the data to programmer or base module upon receiving instructions. In other embodiments, data from the Modules 1 and/or 2, the processor, or implanted medical device may be uploaded to a remote server on a regular or non-regular basis where a clinician or programmer may access the data to determine whether a potential life threatening or hazardous event due to RUL exists. An example of a remote server includes the Medtronic CareLink® Network, available from Medtronic, Inc. of Minneapolis, Minn.

### Working Example

### Test Procedure and Cycling Data

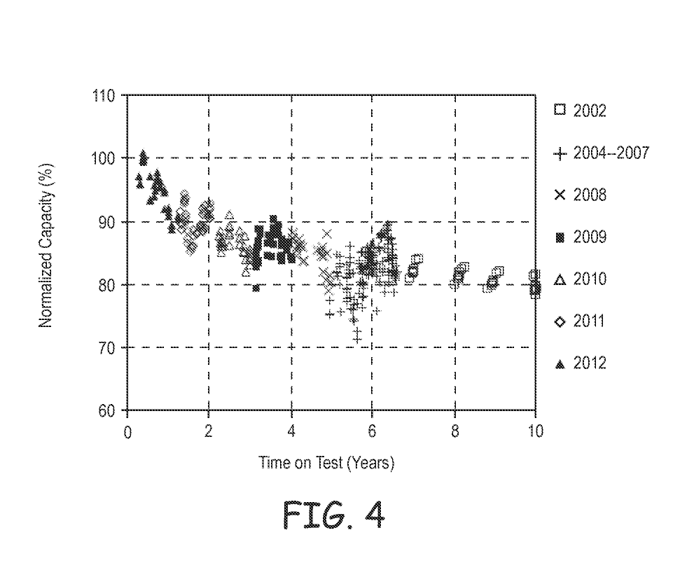

Li-ion cells are constructed in hermetically sealed prismatic cases between 2002 and 2012 and subjected to full depth of discharge cycling with a nominal weekly discharge rate (C/168 discharge) under 37° C. The weekly rate discharge capacities are plotted against the time on test in FIG. 4. It can be observed that the eight cells that started the cycling test in 2002 still have around 80% of the initial capacity remaining after 10 years of continuous cycling. The cycling data from these cells will be used to verify the effectiveness of the proposed method in the capacity estimation and RUL prediction.

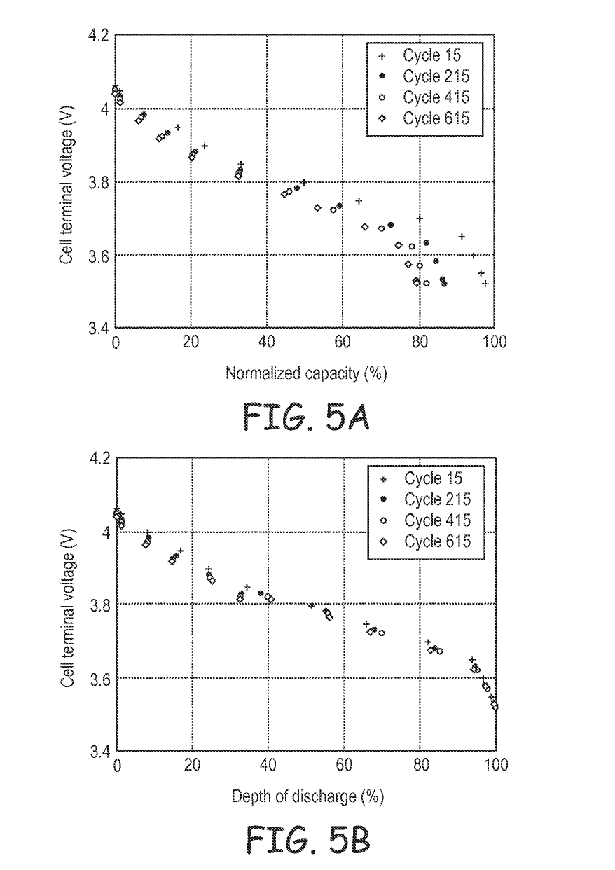

The voltage curve evolution from one cell is graphically plotted against the normalized discharge capacity (relative to the initial discharge capacity) and the depth of discharge (DOD or 1−SOC) in FIG. 5A and FIG. 5B, respectively. It can be observed from FIG. 5A that the voltage versus discharge capacity curves shrink to the left due to the capacity fade over time. In contrast, the voltage versus DOD curve in FIG. 5B exhibited very minor evolutions in the first 2 years and minimal evolutions thereafter. After a certain time delay (greater than 5τ), the diffusion RC circuit in FIG. 2 becomes simply a resistor and, under this extremely low discharge rate, the IR effect is very minimal. Under these two conditions, the cell terminal voltage closely resembles the cell OCV. Thus, the observation from FIG. 5B shows that the relationship between the OCV and DOD remains almost unchanged in the presence of cell ageing. This observation supports the use of the OCV-DOD or OCV-SOC relationship for the capacity estimation as described herein.

### Capacity Estimation

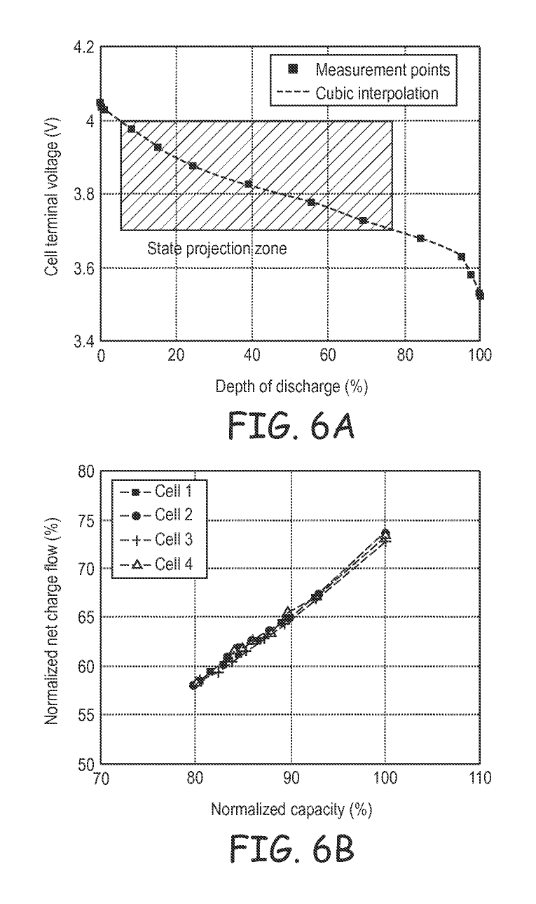

The cell discharge capacity can be estimated based on the state projection scheme described above. For example, an unknown SOC (or 1−DOD) at a specific OCV level can be approximated based on the cubic spline interpolation with a set of known OCV and SOC values as shown in the measurement points and interpolated curve in FIG. 6A. As shown in FIG. 6A, the state projection zone spans an OCV range 4.0V-3.7V. In FIG. 6B, the net charge flow in the state projection zone is plotted as a function of cell discharge capacity for four cells at eight different cycles spanning the whole 10 years' test duration. The graph shows that the net charge flow is a linear function of the cell discharge capacity. This observation suggests that a linear model can be generated to relate the capacity to the current integration. In fact, this linear model is the same one as shown in formula (4). With the SOCs at 4.0 V and 3.7 V derived based on the OCV-SOC relationship and the net charge flow calculated by the coulomb counting, the cell discharge capacity can be computed based on formula (4).

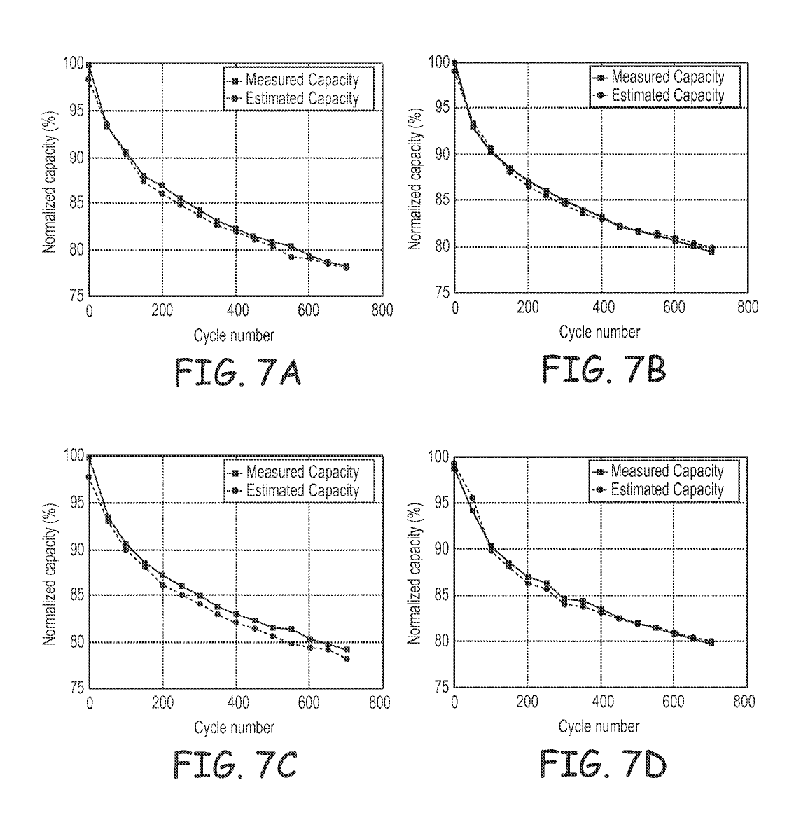

The capacity estimation results for the four cells are shown in FIGS. 7A-7D. For each cell, the normalized capacity is plotted against the cycle number. It can be observed that the capacity estimation method closely tracks the capacity fade trend throughout the cycling test for all the four cells. Table 1 summarized the capacity estimation errors for the four cells. Here, the root mean square (RMS) and maximum errors are formulated as in formula (17)

$${ɛ}_{RMS} = \sqrt{\frac{1}{{N}_{C}} {\sum }_{i = 1}^{{N}_{C}} {( Δ {\hat{C}}_{i} - Δ {C}_{i} )}^{2}} , \\ {ɛ}_{Max} = {max}_{1 \leq i \leq {N}_{C}} \vert Δ {\hat{C}}_{i} - Δ {C}_{i} \vert . \qquad ( 17 )$$

where N_{C} is the number of charge/discharge cycles; and ΔCᵢ and ΔĈᵢ are respectively the measured and estimated normalized capacities at the i^{th} cycle. It can be observed that the average error is less than 1% for any of the four cells and the maximum error is less than 3%. The results suggest that the proposed capacity estimation is capable of producing accurate and robust capacity estimation in the presence of cell-to-cell manufacturing variability.

TABLE 1
Capacity estimation results

| Errors | Cell 1 | Cell 2 | Cell 3 | Cell 4 |
|---|---|---|---|---|
| RMS (%) | 0.52 | 0.51 | 0.88 | 0.52 |
| Max (%) | 2.38 | 2.91 | 2.10 | 2.90 |

### Prediction of RUL

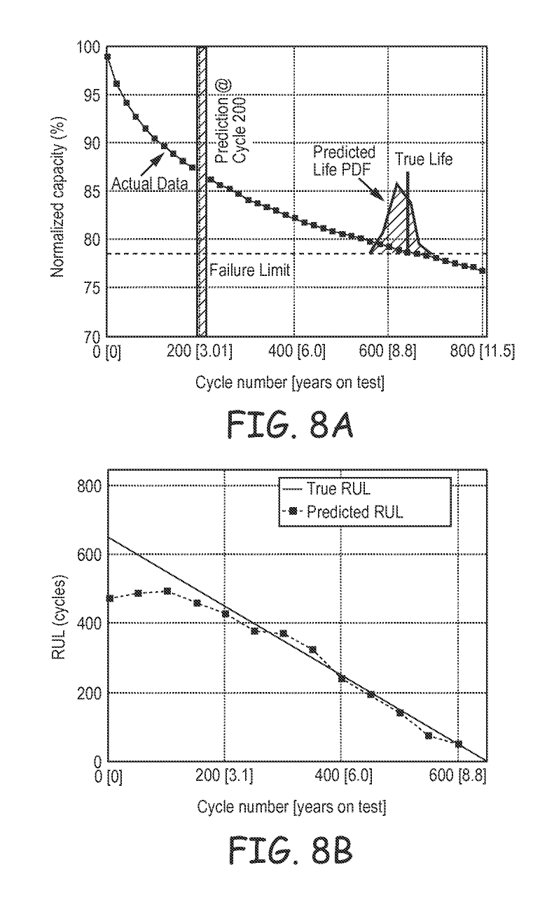

RUL can be used as the relevant metric for determining the SOL of a Li-ion battery as described by the present invention. Based on the capacity estimates, the GHPF technique can be used to project the capacity to the EOS value (or the EOS threshold) for the RUL prediction. In certain embodiments, the EOS threshold can defined as 78.5% of the initial capacity. Other EOS thresholds are contemplated by the invention as described herein and shown by formula (15). For the particular example of a 78.5% EOS threshold, FIG. 7A shows that the discharge capacity of cell 1 at the last cycle (i.e., cycle 717) is still higher than the EOS threshold (i.e., 78.5% of the initial capacity). In certain embodiments, and in order to have a complete run-to-EOS dataset, a nonlinear least-squares fitting can be performed based on the capacity measurements up to cycle 717 and a regression model be generated and then extrapolated to the EOS threshold. Based on the capacity estimates obtained with the state projection scheme, the GHPF technique is used to project the capacity to the EOS value (or the EOS threshold) for the RUL prediction. Here the EOS threshold is defined as 78.5% of the beginning-of-life (BOL) discharge capacity of the cell. FIG. 8A shows the capacity tracking and RUL prediction by the GHPF at cycle 200 (or 3.1 years). It can be observed that the predicted RUL provides a conservative solution and includes the true EOS cycle (i.e., 650 cycles). FIG. 8B plots the RUL predictions by the GHPF at multiple cycles throughout the life-time of the battery. The graph shows that as the RUL distribution are updated throughout the battery life-time, the prediction converges to the true value as the battery approaches its EOS cycle.

It will be apparent to one skilled in the art that various combinations and/or modifications and variations can be made in the methods, system and processors thereof, depending upon the specific needs for operation. Features illustrated or described as being part of one embodiment may be used on another embodiment to yield a still further embodiment.

We claim:

1. A method of predicting remaining useful life (RUL) of a rechargeable battery, comprising the steps of:
(a) determining a capacity of a battery based on at least changes between a first state of charge (SOC) value determined at a first time (SOC1) and a second SOC value determined at a second time (SOC2) and a net charge flow of the battery;
(b) applying a particle filter to a capacity degradation model using the determined capacity to form an adjusted capacity degradation model for the battery; and
(c) predicting the RUL of the battery using the adjusted capacity degradation model with a pre-defined EOS threshold.

2. The method of claim 1, wherein the capacity degradation model can be a hybrid or exponential capacity degradation model.

3. The method of claim 1, wherein the exponential capacity degradation model is expressed by the formula:
$${c}_{i} = \frac{{C}_{i}}{{C}_{0}} = 1 - α [ 1 - exp ( - λi ) ] - βi$$
wherein Cᵢ is a capacity at i^{th} the cycle, C₀ is the initial capacity, α is a coefficient of the exponential component of capacity fade, λ is an exponential capacity fade rate, β is a coefficient of the linear component of capacity fade, and cᵢ is a normalized capacity at the i^{th} cycle.

4. The method of claim 1, wherein the battery is selected from a group consisting of nickel-metal hydride battery, nickel-cadmium battery, lithium-ion polymer battery, lithium sulfur battery, thin film battery, smart battery, carbon foam-based lead acid battery, potassium-ion battery, and sodium-ion battery.

5. The method of claim 1, wherein the SOC1 value is determined as a function of a first open circuit voltage measurement (V1) of the battery made before a partial charge or discharge period and the SOC2 value is determined as a function of a second open circuit voltage measurement (V2) made after a partial charge or discharge period.

6. The method of claim 5, wherein the net charge flow (ΔQ) is determined by measuring the current of the charge and integrating the current over the charge or discharge period.

7. The method of claim 6, wherein the capacity (C) of the battery is determined using the following equation:
C=ΔQ/|SOC1−SOC2|.

8. The method of claim 5, wherein the C is determined using the following equation:
$${C}_{k} = \frac{{\int }_{{t}_{k}}^{{t}_{k + L}} i ( t ) d t}{{SOC}_{k + L} - {SOC}_{k}}$$
wherein Cₖ is the capacity, SOC is the state of charge, k is the index of the measurement time step at the beginning of the partial charge or discharge, L is the number of measurement time steps over the partial charge or discharge, tₖ and t_{k+L} are respectively the time points at the beginning and end of the partial charge or discharge, and i is the current

9. The method of claim 1, wherein the particle filter is selected from a group consisting of a standard sequential importance sampling and resampling particle filter, a standard sequential importance sampling particle filter, a standard sequential importance resampling filter, an extended Kalman filter, an unscented Kalman filter, and a Gauss-Hermite particle filter.

10. The method of claim 9, wherein an optimal proposal importance density used in the particle filter is derived from formula:
q(xᵢ|x_{0:i-1},y_{1:i})=p(xᵢ|xᵢ₋₁,yᵢ)
wherein x is a state estimate and y is a system observation.

11. The method of claim 10, wherein the Gauss-Hermite particle filter is used in the determination of the RUL of the battery, and the method further comprises the steps of:
(a) determining the capacity at an i^{th} cycle;
(b) determining a system transition and a measurement function;
(c) determining a posterior PDF of the normalized capacity by the Gauss-Hermite particle filter;
(d) predicting normalized capacity forward by a cycle number;
(e) determining RUL for each particle; and
(f) determining RUL distribution.

12. The method of claim 11, wherein the determination of system transition and measurement function uses formulas:
cᵢ=1−αᵢ₋₁[1−exp(−λᵢ₋₁i)]−βᵢ₋₁i+uᵢ,αᵢ=αᵢ₋₁+r_{1,i},λᵢ=λᵢ₋₁+r_{2,i},βᵢ=βᵢ₋₁+r_{3,i} Transition:
yᵢ=cᵢ+vᵢ Measurement:
wherein cᵢ is the normalized capacity at the i^{th} cycle, α is the coefficient of the exponential component of capacity fade, λ is the exponential capacity fade rate, β is the coefficient of the linear component of capacity fade, yᵢ is the capacity measurement at the i^{th} cycle, and u, r₁, r₂, r₃ and v are the Gaussian noise variables with zero means.

13. The method of claim 11, wherein determination of a posterior PDF of the normalized capacity by the Gauss-Hermite particle filter uses formula:
$$p ( {c}_{i} \vert {y}_{1 \text{:} i} ) \approx \frac{1}{{N}_{P}} {\sum }_{i = 1}^{{N}_{P}} δ ( {c}_{i} - {c}_{i}^{j} )$$
wherein N_{P} is the number of particles, δ is the Dirac delta function, and cᵢ^{j} is the j^{th} particle after the resampling step at the i^{th} cycle.

14. The method of claim 11, further comprising the step of predicting a normalized capacity forwarded by a cycle number using the formula:
$$p ( {c}_{i + l} \vert {y}_{1 \text{:} i} ) \approx \frac{1}{{N}_{P}} {\sum }_{i = 1}^{{N}_{P}} δ ( {c}_{i + l} - {c}_{i + l}^{j} )$$
wherein cᵢ=1−αᵢ^{j}[1−exp(−λᵢ^{j}(i+l))]−βᵢ^{j}(i+l)
wherein N_{P} is the number of particles, δ is the Dirac delta function, cᵢ^{j} is the j^{th} particle after the resampling step at the i^{th} cycle, αᵢ^{j} is the coefficient of the exponential component of capacity fade, λᵢ^{j} is the exponential capacity fade rate, and βᵢ^{j} is the coefficient of the linear component of capacity fade.

15. The method of claim 11, wherein the step of determining the RUL for the particle as the number of cycles between a current cycle and an end of service cycle (EOS) uses formula:
Lᵢ^{j}=root[αᵢ^{j}[1−exp(−λᵢ^{j}i)]+βᵢ^{j}i=x]−i
wherein αᵢ^{j} is the coefficient of the exponential component of capacity fade, λᵢ^{j} is the exponential capacity fade rate, βᵢ^{j} is the coefficient of the linear component of capacity fade and x=1−pre-defined EOS threshold (%).

16. The method of claim 11, wherein the RUL distribution is determined using formula:
$$p ( {L}_{i} \vert {y}_{1 \text{:} i} ) \approx \frac{1}{{N}_{P}} {\sum }_{i = 1}^{{N}_{P}} δ ( {L}_{i} - {L}_{i}^{j} ) ;$$
wherein N_{P} is the number of particles, and δ is the Dirac delta function.

17. The method of claim 15, wherein the pre-defined EOS threshold is between 20%-90% of the normalized capacity.

18. The method of claim 15, wherein the pre-defined EOS threshold is between 30%-80% of the normalized capacity.

19. The method of claim 15, wherein the pre-defined EOS threshold is between 40%-70% of the normalized capacity.

20. The method of claim 15, wherein the pre-determined EOS threshold is between 50%-60% of the normalized capacity.

21. A system, comprising: an implantable medical device having a rechargeable battery said rechargeable battery having a voltage, a total capacity which changes over time and a charge level; a processor configured to predict the RUL of the rechargeable battery by performing the steps comprising of:
(a) determining a capacity of a battery based on at least changes between a first state of charge (SOC) value determined at a first time (SOC1) and a second SOC value determined at a second time (SOC2) and a net charge flow of the battery;
(b) applying a particle filter to a capacity degradation model using the determined capacity to form an adjusted capacity degradation model for the battery; and
(c) predicting the RUL of the battery using the adjusted capacity degradation model with a pre-defined EOS threshold, electronic componentry, operatively coupled to said implantable medical device, configured to measure electrical signals of the battery used to determine the SOC1 and SOC2 values and net charge flow and transmit the electrical signals or SOC1 SOC2 values and the net charge flow values to the processor; and a user output, operatively coupled to said electrical componentry or processor, configured to communicate said RUL to a user.

22. The system of claim 21, wherein the battery is selected from a group consisting of nickel-metal hydride battery, nickel-cadmium battery, lithium-ion polymer battery, lithium sulfur battery, thin film battery, smart battery, carbon foam-based lead acid battery, potassium-ion battery, and sodium-ion battery.

23. The system of claim 21, wherein electronic componentry is configured to make a first open circuit voltage measurement (V1) before a partial charge or discharge period and to make a second open circuit voltage measurement after the partial charge or discharge period (V2) and to communicate V1 and V2 to the processor.

24. The system of claim 21, wherein the electronic componentry is configured to make a first open circuit voltage measurement (V1) before a partial charge or discharge period and to determine the SOC1 value as a function of V1 and to make a second open circuit voltage measurement after the partial charge or discharge period (V2) and to determine the SOC2 value as a function of V2 and to communicate SOC1 and SOC2 to the processor.

25. The system of claim 23, wherein the electronic componentry is further configured to measure the current of the battery charge and communicate the measured current value to the processor.

26. The system of claim 25, wherein the processor is configured to determine the net charge flow (ΔQ) by integrating the current over the charge or discharge period.
